(19) United States
(12) Patent Application Publication
(10) Pub. No.: US 2025/0087915 A1
(43) Pub. Date: Mar. 13, 2025

(54) CONNECTOR-ATTACHED CABLE

(71) Applicant: SUMITOMO ELECTRIC INDUSTRIES, LTD., Osaka (JP)

(72) Inventors: Naoshige YOKOTA, Tochigi (JP); Takami SAGISAKA, Tochigi (JP); Nobuyuki YAMAZAKI, Tochigi (JP); Wataru SAKURAI, Tochigi (JP)

(73) Assignee: SUMITOMO ELECTRIC INDUSTRIES, LTD., Osaka (JP)

(21) Appl. No.: 18/822,359

(22) Filed: Sep. 2, 2024

(30) Foreign Application Priority Data
Sep. 11, 2023 (JP) 2023-146880

(51) Int. Cl. H01R 12/53; H01B 3/44; H01B 11/18

(52) U.S. Cl. CPC H01R 12/53; H01B 3/441; H01B 11/1895

(57) ABSTRACT

A connector-attached cable includes a cable including a plurality of coaxial wires; and a connector connected to the cable, the connector includes a circuit board and a ground bar connected to the coaxial wires, each of the coaxial wires includes a center conductor, an insulating layer covering the center conductor, an outer conductor covering the insulating layer, and a jacket covering the outer conductor. The plurality of coaxial wires are divided into a first group and a second group. A center line of each of the plurality of coaxial wires along an axial direction thereof is disposed in a manner of not overlapping the outer conductor of another coaxial wire. The ground bar is implemented by a single member, and the outer conductors of all of the coaxial wires are connected to the ground bar.

### TECHNICAL FIELD

The present disclosure relates to a connector-attached cable. This application claims priority based on Japanese Patent Application No. 2023-146880 filed on Sep. 11, 2023, and the entire contents of which are incorporated herein by reference.

### BACKGROUND ART

WO2021/161570 discloses an example of a connector-attached cable in which a pair of coaxial wires are respectively connected to front and back of a circuit board.

### SUMMARY

A connector-attached cable according to an aspect of the present disclosure includes a cable including a plurality of coaxial wires; and a connector connected to the cable,
the connector includes a circuit board and a ground bar connected to the coaxial wires,
each of the coaxial wires includes a center conductor, an insulating layer covering the center conductor, an outer conductor covering the insulating layer, and a jacket covering the outer conductor,
at each of end portions of the plurality of coaxial wires, the center conductor, the insulating layer, and the outer conductor are exposed in this order,
the plurality of coaxial wires are divided into a first group and a second group,
the coaxial wires in the first group are connected to a first surface of the circuit board,
the coaxial wires in the second group are connected to a second surface of the circuit board,
in a projection view of the plurality of coaxial wires on the circuit board seen from a direction orthogonal to the first surface or the second surface,
a center line of each of the plurality of coaxial wires along an axial direction thereof is disposed in a manner of not overlapping the outer conductor of another coaxial wire,
the ground bar is implemented by a single member, and
the outer conductors of all of the coaxial wires are connected to the ground bar.

### BRIEF DESCRIPTION OF DRAWINGS

FIG. 1 is a schematic perspective view showing an example of a connector-attached cable according to the present disclosure.

FIG. 2 is an enlarged view of an end portion of a cable shown in FIG. 1.

FIG. 3 is a schematic perspective view showing an example of a connection form between a circuit board and coaxial wires according to the present disclosure.

FIG. 4 is a top view showing the connection form of the connector-attached cable shown in FIG. 3.

FIG. 5 is a bottom view showing the connection form of the connector-attached cable shown in FIG. 3.

FIG. 6 is a cross-sectional view orthogonal to an axial direction showing the connection form of the connector-attached cable shown in FIG. 3.

### DESCRIPTION OF EMBODIMENTS

In the connector-attached cable described in WO2021/161570, it is required to process electronic wires a plurality of times when grounding the electronic wires.

An object of the present disclosure is to provide a connector-attached cable capable of simplifying a step of connecting electronic wires.

According to the above, in the connector-attached cable, a step of connecting the electronic wires is simplified.

### DESCRIPTION OF EMBODIMENTS OF PRESENT DISCLOSURE

First, an embodiment of the present disclosure will be listed and described.

(1) A connector-attached cable according to an aspect of the present disclosure includes:
a cable including a plurality of coaxial wires; and
a connector connected to the cable,
the connector includes a circuit board and a ground bar connected to the coaxial wires,
each of the coaxial wires includes a center conductor, an insulating layer covering the center conductor, an outer conductor covering the insulating layer, and a jacket covering the outer conductor,
at each of end portions of the plurality of coaxial wires, the center conductor, the insulating layer, and the outer conductor are exposed in this order,
the plurality of coaxial wires are divided into a first group and a second group,
the coaxial wires in the first group are connected to a first surface of the circuit board,
the coaxial wires in the second group are connected to a second surface of the circuit board,
in a projection view of the plurality of coaxial wires on the circuit board seen from a direction orthogonal to the first surface or the second surface,
a center line of each of the plurality of coaxial wires along an axial direction thereof is disposed in a manner of not overlapping the outer conductor of another coaxial wire,
the ground bar is implemented by a single member, and
the outer conductors of all of the coaxial wires are connected to the ground bar.

According to the configuration, the ground bar is implemented by a single member, and the outer conductors of all of the coaxial wires connected to the first surface and the second surface of the circuit board and arranged two-dimensionally can be connected to the single ground bar. Further, the plurality of coaxial wires are arranged in a manner of not overlapping each other or having a small overlapping amount when viewed from a direction orthogonal to the surface of the circuit board. Accordingly, a connection step when connecting the cable including the coaxial wires to the connector can be simplified.

(2) In the above (1), the ground bar may include a stepped portion including at least a first step and a second step, the outer conductors of the coaxial wires in the first group may be connected to the first step, and the outer conductors of the coaxial wires in the second group may be connected to the second step.

According to the configuration, the two-dimensionally arranged coaxial wires can be grounded by one surface of the ground bar. Accordingly, when the coaxial wires and the ground bar are adhered to each other by soldering or a conductive adhesive, the coaxial wires can be connected to the surfaces of the single ground bar on the same side. Thus, according to the present disclosure, the step of connecting the coaxial wires can be simplified.

(3) In the above (1) or (2), the ground bar may have a plurality of connection surfaces parallel to the circuit board, and the outer conductors of all of the coaxial wires may be connected to the plurality of connection surfaces.

According to the configuration, the ground bar has the connection surfaces parallel to the circuit board. Accordingly, the coaxial wires connected to the ground bar are connected side by side in parallel to the circuit board, so that the coaxial wires can be easily processed. Therefore, a connector-attached cable capable of simplifying the step of connecting the coaxial wires can be simplified.

(4) In the anyone of (1) to (3), the coaxial wires may be connected in one or more pairs to each of the first surface and the second surface.

(5) In the anyone of (1) to (4), the coaxial wires may be connected to both end portions of the circuit board in an arrangement direction of the coaxial wires on the first surface of the circuit board, and may be connected to a center portion of the circuit board in the arrangement direction of the coaxial wires on the second surface of the circuit board.

(6) In the anyone of (1) to (5), the outer conductor may be connected to the ground bar via a conductive adhesive.

(7) In the above (6), the insulating layer may be made of thermoplastic elastomer or polyolefin.

(8) In the above (6), the insulating layer may contain at least polyethylene or polypropylene.

### Details of Embodiment of Present Disclosure

A specific example of a connector-attached cable according to an embodiment of the present disclosure will be described below with reference to the drawings. The present disclosure is not limited to these exemplifications, but is indicated by the scope of claims, and is intended to include all changes within a scope and meaning equivalent to the scope of claims.

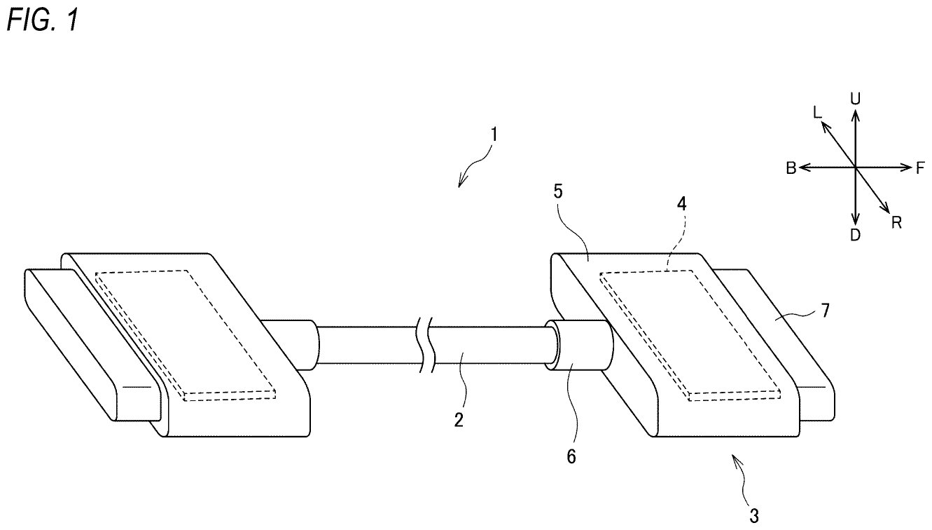

It should be noted that U, D, F, B, R, and L shown in FIG. 1 and the like indicate directions of a connector-attached cable 1, and U indicates an upper direction, D indicates a lower direction, F indicates a front direction, B indicates a rear direction, R indicates a right direction, and L indicates a left direction.

FIG. 1 is a schematic perspective view showing an example of the connector-attached cable 1 according to the present disclosure. The connector-attached cable 1 according to the present embodiment can be used, for example, for connecting electronic devices (not shown) to each other, and a connector 3 is provided on an end portion of a cable 2. As shown in FIG. 1, the connector-attached cable 1 includes the cable 2 and the connector 3.

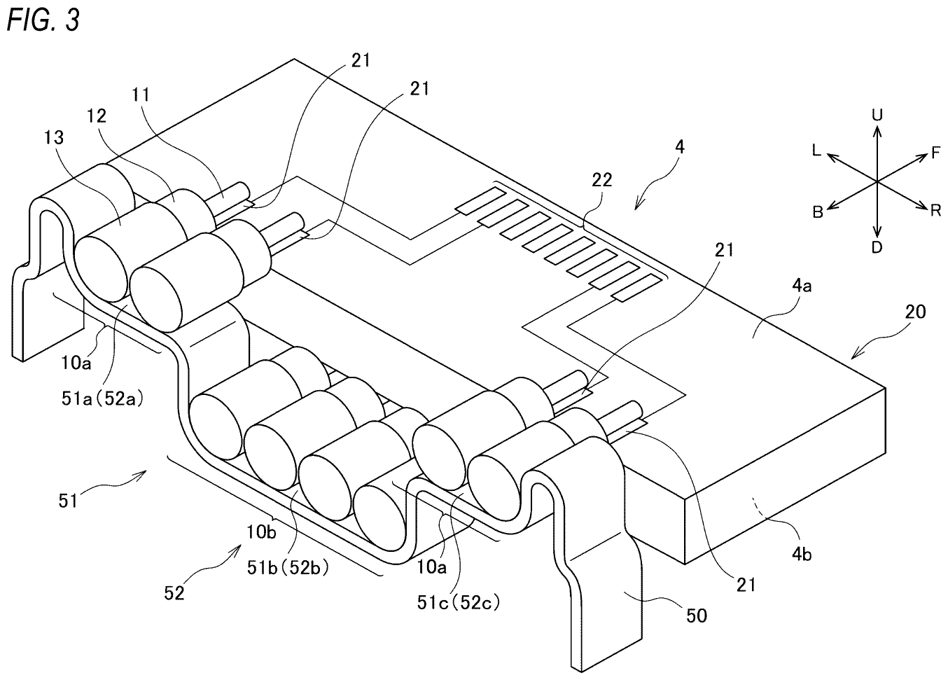

As shown in FIG. 1, the connector 3 includes a circuit board 4, a housing 5 covering the circuit board 4, and a connection portion 7. The circuit board 4 includes a wiring portion 20 (30) on which a circuit pattern is printed on a front surface facing an upward direction (U direction) and a back surface facing a downward direction (D direction) (see FIG. 3). A boot 6 for protecting a connection part between the cable 2 and the connector 3 is provided at one end of the housing 5. In the following description, for convenience of description, a direction from a central portion of the connector 3 toward the connection portion 7 is referred to as the front direction F, and a direction from the central portion of the connector 3 toward the boot 6 that is opposite to the front direction F is referred to as the rear direction B. The connection portion 7 protrudes toward the front direction F. The connection portion 7 is provided with a plurality of device-side wiring portions (not shown). When the connector-attached cable 1 is connected to electronic devices, a device-side wiring portions are electrically connected to wiring in the electronic device.

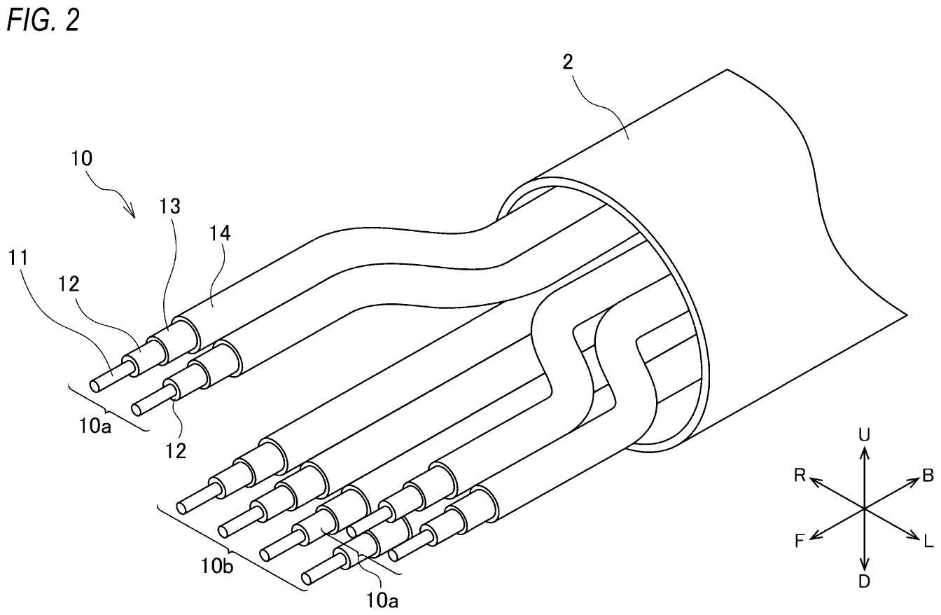

Next, the cable 2 according to the present embodiment will be described with reference to FIG. 2. FIG. 2 is an enlarged view of a front end portion of the cable 2 shown in FIG. 1.

As shown in FIG. 2, the cable 2 includes a plurality of coaxial wires 10. The coaxial wire 10 includes a center conductor 11, an insulating layer 12 covering the center conductor 11, an outer conductor 13 covering the insulating layer 12, and a jacket 14 covering the outer conductor 13. The coaxial wire 10 is step-stripped at an end portion thereof in the front direction F so as to expose the center conductor 11, the insulating layer 12, and the outer conductor 13 in this order.

The center conductor 11 is a single wire made of a conductive metal such as a copper alloy or a twisted wire formed by twisting a plurality of thin wires. The insulating layer 12 is made of an insulating resin, and electrically insulates the center conductor 11 from the surroundings while protecting the center conductor 11. The outer conductor 13 is implemented by a metal braid, metal plating, or the like, prevents leakage of a signal flowing through the center conductor 11, and prevents external radio waves from entering the center conductor 11. The jacket 14 is made of an insulating resin, and prevents damage to the outer conductor 13 while electrically insulating the outer conductor 13 from the outside.

A plurality of the coaxial wires 10 are arranged in a plurality of pairs, and are divided into a first group 10a and a second group 10b as shown in FIG. 2. In the present embodiment, the coaxial wires 10 are connected in pairs to the circuit board 4. Each of the first group 10a and the second group 10b includes at least one pair (two pairs in this example) of coaxial wires 10.

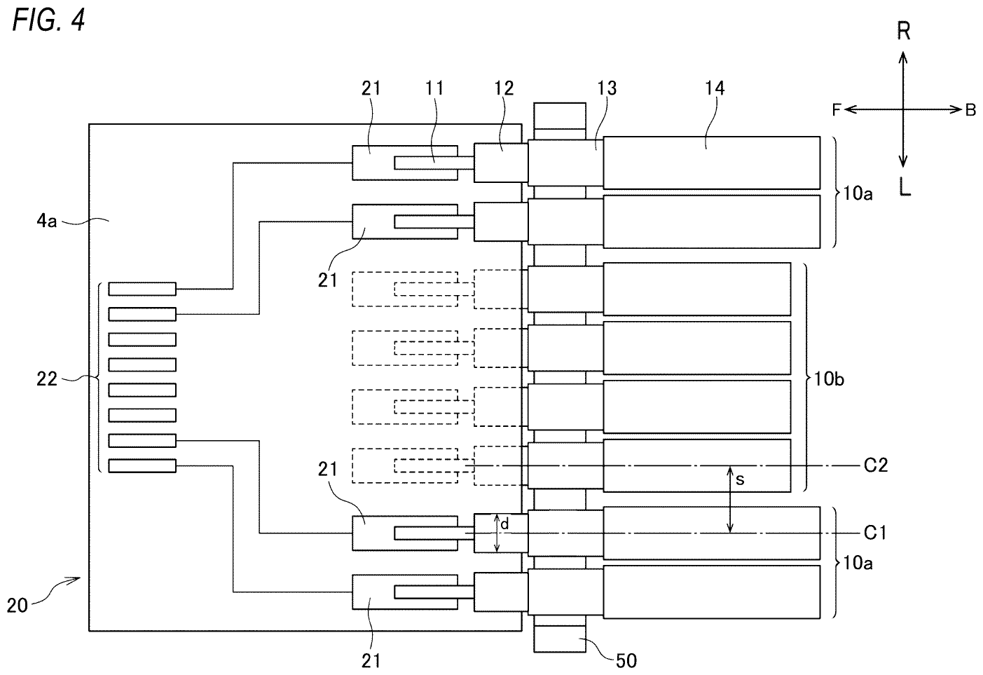

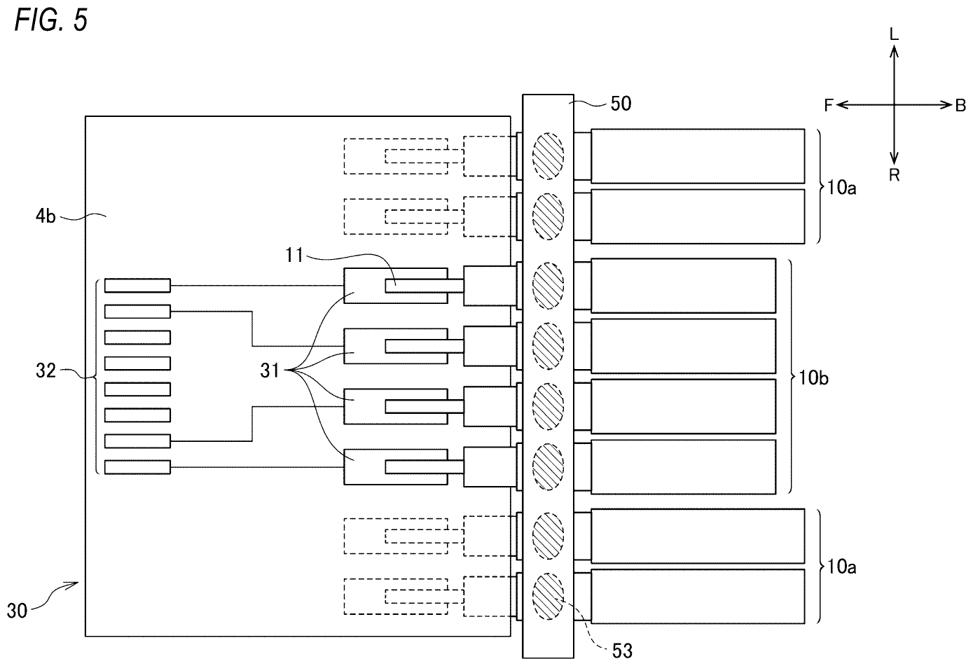

Next, a connection form between the coaxial wires 10 and the circuit board 4 in the present embodiment will be described with reference to FIGS. 3, 4 and 5. FIG. 3 is a schematic perspective view showing an example of a connection form between the circuit board and the coaxial wires according to the present disclosure. FIG. 4 is a top view showing the connection form of the connector-attached cable shown in FIG. 3. FIG. 5 is a bottom view showing the connection form of the connector-attached cable shown in FIG. 3.

As shown in FIG. 3, the connector 3 includes the circuit board 4 and a ground bar 50. The circuit board 4 has a first surface 4a on the front surface and a second surface 4b on the back surface. The first surface 4a includes the wiring portion 20 to which an electronic wire can be connected. As shown in FIGS. 3 and 4, the wiring portion 20 on the first surface 4a includes wire pads 21 to which the coaxial wires 10 can be connected, and connector pads 22. As shown in FIGS. 3 and 5, the second surface 4b includes the wiring portion 30 similarly to the first surface 4a, and the wiring portion 30 includes wire pads 31 and connector pads 32 similarly to the wiring portion 20. The connector pads 22 on the first surface 4a and the connector pads 32 on the second surface 4b are configured to be electrically connected to an electrical device (not shown) connected to the connector 3.

An end portion of the coaxial wire 10 in the F direction is step-stripped and connected to the circuit board 4 and the ground bar 50. The coaxial wires 10 and the circuit board 4 are connected by soldering the center conductors 11 to the wire pads 21 on the wiring portion 20 or the wire pads 31 on the wiring portion 30 provided on the circuit board 4. The first group 10a of the coaxial wires 10 is connected to the first surface 4a of the circuit board 4, and the second group 10b of the coaxial wires 10 is connected to the second surface 4b of the circuit board 4. The center conductors 11 of the coaxial wires 10 in the first group 10a are connected to the wire pads 21 on the first surface 4a. The center conductors 11 of the coaxial wires 10 in the second group 10b are connected to the wire pads 31 on the second surface 4b. The coaxial wires 10 are connected to each of the first surface 4a and the second surface 4b in one or more pairs.

The ground bar 50 shown in FIG. 3 is a member that is implemented by a single member and can ground the outer conductors 13 of the coaxial wires 10. The ground bar 50 is connected to a grounding terminal of the circuit board 4 or a shell (not shown) in the connector. The ground bar 50 is a thin plate-shaped member formed to extend in a width direction of the circuit board 4, and includes a stepped portion 51 having at least two (three in this example) steps, and a plurality of connection surfaces 52. Each of the coaxial wires 10 is connected to any of the plurality of connection surfaces 52.

In the present embodiment, the ground bar 50 includes the stepped portion 51 including a first step 51a, a first step 51c, and a second step 51b, and all of the steps in the stepped portion 51 also function as the connection surfaces 52. In the present embodiment, the first step 51a has a first connection surface 52a, the second step 51b has a second connection surface 52b, and the first step 51c has a third connection surface 52c. The first step 51a and the first step 51c are formed to have the same height in a direction orthogonal to the surfaces of the circuit board 4, and the second step 51b is formed to have a height one step lower than the first step 51a and the first step 51c. A difference in height between the first steps 51a, 51c and the second step 51b is substantially equal to a sum of a thickness of the circuit board 4 and an outer diameter of the outer conductor 13.

The coaxial wires 10 and the ground bar 50 are connected by connecting the outer conductors 13 and the ground bar 50 at the connection surfaces 52. As shown in FIG. 5 in a transparent manner, adhesive portions 53 such as solder or conductive adhesive are provided at connection points between the outer conductors 13 and the ground bar 50 in order to fix the connection form while making potentials of the both equal to each other. In the first group 10a of the coaxial wires 10, the outer conductors 13 are disposed on the first step 51a (first connection surface 52a) and the first step 51c (third connection surface 52c) and are connected by the adhesive portions 53. The coaxial wires 10 in the first group 10a are arranged in the same plane along the first surface 4a of the circuit board 4, and are connected to the first step 51a and the first step 51c which have the same height on the ground bar 50. The second group 10b of the coaxial wires 10 is arranged in the same plane along the second surface 4b of the circuit board 4, is disposed on the second step 51b (second connection surface 52b), and is connected by the adhesive portions 53.

The plurality of coaxial wires 10 are arranged in a manner of not overlapping with each other or having a small overlapping amount at a portion connected to the ground bar 50 in the top view shown in FIG. 4 or in the bottom view shown in FIG. 5. That is, as shown in FIGS. 4 and 5, the coaxial wires 10 in the first group 10a connected to the first surface 4a and the coaxial wires 10 in the second group 10b connected to the second surface 4b are arranged along the width direction of the circuit board 4 and do not overlap each other.

As shown in FIGS. 4 and 5, in the connector-attached cable according to the present disclosure, when the coaxial wires 10 are viewed in a projection view seen from a direction orthogonal to the first surface 4a or the second surface 4b, a center line (for example, a center line C1 or a center line C2 in FIG. 4) of the coaxial wire 10 along an axial direction thereof is disposed in a manner of not overlapping the outer conductor 13 of another coaxial wire 10.

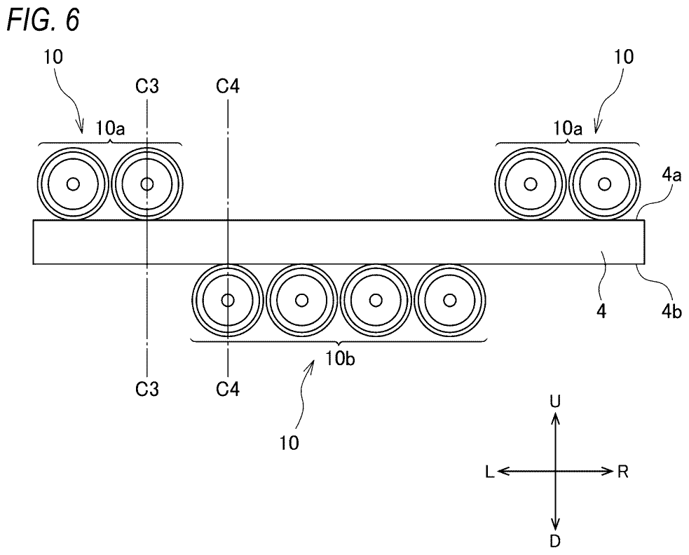

Here, in order to describe the above configuration in detail, FIG. 6 will be referred to. FIG. 6 is a cross-sectional view orthogonal to the axial direction showing the connection form of the connector-attached cable shown in FIG. 3. As shown in FIG. 6, each of the center lines of the coaxial wires 10 connected to the first surface 4a and the second surface 4b is disposed in a manner of not overlapping the outer conductor of another coaxial wire 10. For example, when center lines of two coaxial wires connected to different surfaces in FIG. 6 and having a shortest distance in the LR direction are set as C3 and C4, the coaxial wire 10 having the center line C3 is disposed in a manner of not overlapping the outer conductor of the coaxial wire 10 having the center line C4 and connected to the second surface 4b.

As shown in FIGS. 4, 5, and 6, in the present embodiment, the coaxial wires 10 are connected to both end portions in the width direction of the circuit board 4 in an arrangement direction of the coaxial wires 10 on the first surface 4a of the circuit board 4, and are connected to a center portion of the circuit board 4 in the arrangement direction of the coaxial wires 10 on the second surface 4b of the circuit board 4.

Although not shown in FIGS. 2 to 6 for the sake of visibility, the cable 2 may further include electronic wires other than the coaxial wires 10. Further, the electronic wires other than the coaxial wires 10 may be connected to the circuit board 4.

In a connector-attached cable in the related art, when grounding a coaxial wire, an outer conductor of the coaxial wire may be connected to a ground pad provided on a circuit board or a ground bar provided separately from the circuit board. When connecting the coaxial wire to the circuit board or the ground bar, in order to expose a center conductor and the outer conductor, it is required to irradiate the coaxial wire with a laser to step-strip the coaxial wire. From a viewpoint of efficiency of a connection step, step-stripping of the coaxial wires is often performed in an arrangement state immediately before the coaxial wires are connected to the circuit board or the ground bar. However, when connecting a plurality of coaxial wires to both surfaces of the circuit board, it is required to remove coatings of the coaxial wires by a laser or the like for each surface to which the coaxial wires are to be connected, and then connect the coaxial wires to a ground bar different for each surface of the circuit board, which is complicated.

Therefore, the present inventors have found that the connection step can be simplified by connecting the outer conductors of all of the coaxial wires to a single ground bar separated from the circuit board.

According to the connector-attached cable 1 of the present disclosure, the ground bar 50 is implemented by a single member, and the outer conductors 13 of all of the coaxial wires 10 connected to the first surface 4a and the second surface 4b of the circuit board 4 and arranged two-dimensionally can be connected to the single ground bar 50. Further, the plurality of coaxial wires are arranged in a manner of not overlapping each other or having a small overlapping amount when viewed from a direction orthogonal to the surface of the circuit board.

Accordingly, a connection step when connecting the plurality of coaxial wires 10 in the cable 2 to the circuit board 4 can be simplified. Further, since it is not necessary to separately provide the ground bar for each surface of the circuit board, the number of components can be reduced.

In the above-described embodiment, thermoplastic elastomer or polyolefin may be used as the insulating resin forming the insulating layer 12. By using these materials, an amount of fluorine used can be reduced. Further, the thermoplastic elastomer may include polyethylene or polypropylene. When the thermoplastic elastomer or the polyolefin as described above is used as the insulating layer 12 of the coaxial wire 10, in order to avoid melting of the insulating layer 12 caused by heat, the coaxial wire 10 may be adhered to the ground bar 50 using a conductive adhesive, that allows adhesion without heating, as the adhesive portion 53.

When the coaxial wires 10 are connected to both end portions of the circuit board 4 in the arrangement direction of the coaxial wires 10 on the first surface 4a of the circuit board 4 and are connected to a center portion of the circuit board 4 in the arrangement direction of the coaxial wires 10 on the second surface 4b of the circuit board 4 as in the present embodiment, in the top projection view as shown in FIG. 4, a diameter d of the insulating layer 12 and a distance S between the center lines of the coaxial wires 10 may satisfy a relationship of the following Formula (1).

$$S \geq 0.85 d \qquad ( 1 )$$

By arranging the coaxial wires 10 to satisfy the above relational formula, an area in which the coaxial wires 10 overlap each other in a top view or a bottom view can be reduced. Then, the outer conductors of all of the coaxial wires can be connected to a single ground bar.

Although the embodiment of the present disclosure has been described above, it goes without saying that the technical scope of the present disclosure should not be interpreted to be limited by the description of the present embodiment. The present embodiment is merely an example, and it is understood by those skilled in the art that various modifications can be made to the present embodiment within the scope of the invention described in the claims. The technical scope of the present disclosure should be defined based on the scope of the invention described in the claims and the scope of equivalents thereof.

1. A connector-attached cable comprising:
a cable including a plurality of coaxial wires; and
a connector connected to the cable, wherein
the connector includes a circuit board and a ground bar connected to the coaxial wires,
each of the coaxial wires includes a center conductor, an insulating layer covering the center conductor, an outer conductor covering the insulating layer, and a jacket covering the outer conductor,
at each of end portions of the plurality of coaxial wires, the center conductor, the insulating layer, and the outer conductor are exposed in this order,
the plurality of coaxial wires are divided into a first group and a second group,
the coaxial wires in the first group are connected to a first surface of the circuit board,
the coaxial wires in the second group are connected to a second surface of the circuit board,
in a projection view of the plurality of coaxial wires on the circuit board seen from a direction orthogonal to the first surface or the second surface,
a center line of each of the plurality of coaxial wires along an axial direction thereof is disposed in a manner of not overlapping the outer conductor of another coaxial wire,
the ground bar is implemented by a single member, and
the outer conductor of each of the coaxial wires is connected to the ground bar.

2. The connector-attached cable according to claim 1, wherein
the ground bar includes a stepped portion including at least a first step and a second step,
the outer conductor of each of the coaxial wires in the first group is connected to the first step, and
the outer conductor of each of the coaxial wires in the second group is connected to the second step.

3. The connector-attached cable according to claim 1, wherein
the ground bar has a plurality of connection surfaces parallel to the circuit board, and the outer conductor of each of the coaxial wires is connected to each of the plurality of connection surfaces.

4. The connector-attached cable according to claim 1, wherein
the coaxial wires are connected in one or more pairs to each of the first surface and the second surface.

5. The connector-attached cable according to claim 1, wherein
the coaxial wires are connected to both end portions of the circuit board in an arrangement direction of the coaxial wires on the first surface of the circuit board, and are connected to a center portion of the circuit board in the arrangement direction of the coaxial wires on the second surface of the circuit board.

6. The connector-attached cable according to claim 1, wherein
the outer conductor is connected to the ground bar via a conductive adhesive.

7. The connector-attached cable according to claim 6, wherein
the insulating layer is made of thermoplastic elastomer or polyolefin.

8. The connector-attached cable according to claim 6, wherein
the insulating layer contains at least polyethylene or polypropylene.
